(19) United States
(12) Patent Application Publication
(10) Pub. No.: US 2011/0262769 A1
(43) Pub. Date: Oct. 27, 2011

(54) SURFACE HARDENED SUBSTRATE AND METHOD MAKING SAME

(75) Inventors: HSIN-PEI CHANG, Tu-Cheng (TW); WEN-RONG CHEN, Tu-Cheng (TW); CHENG-SHI CHEN, Tu-Cheng (TW); HUAN-WU CHIANG, Tu-Cheng (TW); DAI-YU SUN, Shenzhen City (CN); CONG LI, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 12/884,681

(22) Filed: Sep. 17, 2010

(30) Foreign Application Priority Data
Apr. 23, 2010 (CN) 201010154147.8

(51) Int. Cl. B32B 15/04; C23C 14/34; B32B 15/01

(52) U.S. Cl. 428/627; 428/655; 428/621; 204/192.1; 428/656; 428/457; 428/684

(57) ABSTRACT

A surface hardened substrate includes a base, a transition layer disposed on a surface of the base, and a hard layer disposed on the transition layer. The transition layer includes at least two kinds of transition metals. The hard layer includes a composite that comprises the at least two kinds of transition metals and a nonmetal.

### CROSS-REFERENCE TO RELATED APPLICATION

This application claims all benefits accruing under 35 U.S.C. §119 from China Patent Application No. 201010154147.8, filed on Apr. 23, 2010, in the China

Intellectual Property Office, disclosure of which is incorporated herein by reference. This application is related to an application entitled, “SURFACE HARDENED SUBSTRATE AND METHOD MAKING SAME,” filed **** (Atty. Docket No. U.S.30313).

### BACKGROUND

1. Technical Field

The present disclosure relates to a surface hardened substrate and a method for making the same.

2. Description of Related Art

An enhanced film generally is disposed on a surface of a substrate such as a watch shell, an eyeglass frame, a mobile telephone, or a computer, to protect the substrate from being scratched. The enhanced film can have a high wearing resistance, and a high mechanical hardness.

However, the enhanced film such as chromium carbide (CrC) film, or chromium nitride (CrN) film, is brittle. There is a low bonding tension between the enhanced film and the substrate such that the enhanced film is prone to get broken off from the substrate.

What is needed, therefore, is to provide a surface hardened substrate with an enhanced film disposed thereon and a method making the surface hardened substrate, in which the enhanced film is difficult to break off from the substrate.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a schematic structural view of an embodiment of a surface hardened substrate.

FIG. 2 is a schematic structural view of an embodiment of a surface hardened substrate.

FIG. 3 shows a glow discharge optical emission spectrometry (GD-OES) image of the surface hardened substrate of the embodiment shown in FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

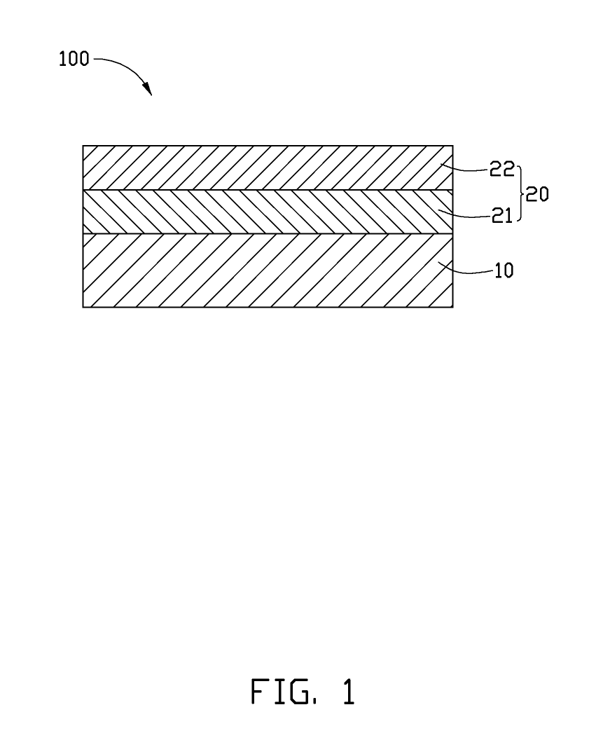

Referring to FIG. 1, one embodiment of a surface hardened substrate 100 is shown. The surface hardened substrate 100 includes a base 10 and an enhanced film 20 disposed on a surface of the base 10.

The base 10 can be a watch shell, an eyeglass frame, a mobile telephone, or a computer. The base 10 can be a metal-based base such as a magnesium-based base, an aluminum-based base, or an iron-based base. The base 10 can be a composite-based base including a metal complex. In one embodiment, the base 10 is steel-based.

The enhanced film 20 can cover the surface of the base 10 and protect the base 10 from being eroded or scratched. The enhanced film 20 can have a thickness greater than about 200 nanometers. In one embodiment, the enhanced film 20 has a thickness from about 500 nanometers to about 5 micrometers. The enhanced film 20 can be a multilayer structure. The enhanced film 20 can include a transition layer 21 disposed on the surface of the base 10, and a hard layer 22 disposed on the transition layer 21.

The transition layer 21 is substantially sandwiched between the base 10 and the hard layer 22 to improve an adhesion between the base 10 and the hard layer 22.

The transition layer 21 can include nickel (Ni) and chromium (Cr). The nickel can be a composite with chromium to form a Ni—Cr alloy. Alternatively, the transition layer 21 can be an alloy based on the nickel and the chromium. The nickel has good tenacity, and stability in high temperature, and good adhesion with the base 10. The chromium can improve the mechanical hardness of the transition layer 21. The nickel in the transition layer 21 can have a weight percent from about 20 percent to about 80 percent, and can have a thickness from about 100 nanometers to about 3 micrometers. In one embodiment, to improve an adhesion between the base 10 and the enhanced film 20 and save a cost of the transition layer 21, the weight percent of the nickel is about 60 percent, and the thickness of the transition layer 21 is about 150 nanometers.

The hard layer 22 can be disposed on a surface of the transition layer 21 away from the base 10. The hard layer 22 can include nickel, chromium, and nitrogen (N) or carbon (C). The nickel and the chromium can be a composite with nitrogen or carbon to form a Ni—Cr—N alloy, a Ni—Cr—C alloy, or a Ni—Cr—N—C alloy. In one embodiment, the hard layer 22 is a Ni—Cr—N—C alloy layer. A hard phase can be formed by nitrogen or carbon with nickel and chromium to improve mechanical hardness and wear resistance of the hard layer 22. Both the transition layer 21 and the hard layer 22 can have nickel and chromium, thus, the transition layer 21 and the hard layer 22 can be adhered together tightly. A thickness of the hard layer 22 can be designed as practical application. In one embodiment, the thickness of the hard layer 22 is in a range from about 100 nanometers to about 3 micrometers. Weight percents of nickel, chromium, and nitrogen or carbon can be designed as practical application. The nitrogen in the hard layer 22 can have a weight percent from about 1 percent to about 50 percent, the carbon in the hard layer 22 can have a weight percent from about 1 percent to about 50 percent. The weight percent of the nitrogen plus the weight percent of the carbon can be of about 1 percent to about 90 percent. In one embodiment, the hard layer 22 obtains excellent adhesion with the transition layer 21 and high mechanical hardness, if the weigh percent of nickel is about 62 percent, the weight percent of chromium is about 16 percent, the weight percent of carbon is about 12 percent, and the weight percent of nitrogen is about 10 percent.

The transition metals in the transition layer 21 and the hard layer 22 cannot be limited. If only two kinds of the transition metals can be contained in the transition layer 21 and the hard layer 22. The transition metals in the transition layer 21 are substantially the same as the transition metals in the hard layer 22. The transition metals can also be rhodium, cobalt, manganese, titanium, tungsten, palladium, cadmium, zirconium, or combinations thereof. One of the at least two kinds of the transition metals, such as nickel, or titanium, can have an excellent adhesion with the base 10. The other one of the two kinds of the at least two kinds of transition metals, such as tungsten, or chromium, can form a hard phase with the nonmetal to improve the mechanic hardness and the wearing resistance of the enhanced film 20.

The enhanced film 20 can be firmly fixed on the base 10, due to the excellent adhesion of the transition layer 21. Thus, the enhanced film 20 can be tightly adhered to the base 10. The hard layer 22 having high mechanical hardness and high wearing resistance can protect the base 10 from being scratched. In addition, both the transition layer 21 and the hard layer 22 can have the at least two kinds of transition metals such as nickel and chromium therein, therefore, a thermal expansion coefficient of the transition layer 21 can be substantially equal to a thermal expansion coefficient of the hard layer 22. A Young's modulus of the transition layer 21 can be similar to a Young's modulus of the hard layer 22. When a temperature of the surface hardened substrate 100 is changed, a volume of the enhance film 20 will change with the temperature. A deformation of the transition layer 21 can be substantially equal to a deformation of the hard layer 22, thus, an intensity of internal stress formed in the enhanced film 20 can be decreased. Thus, the enhanced film 20 can be difficult to brake off from the base 10.

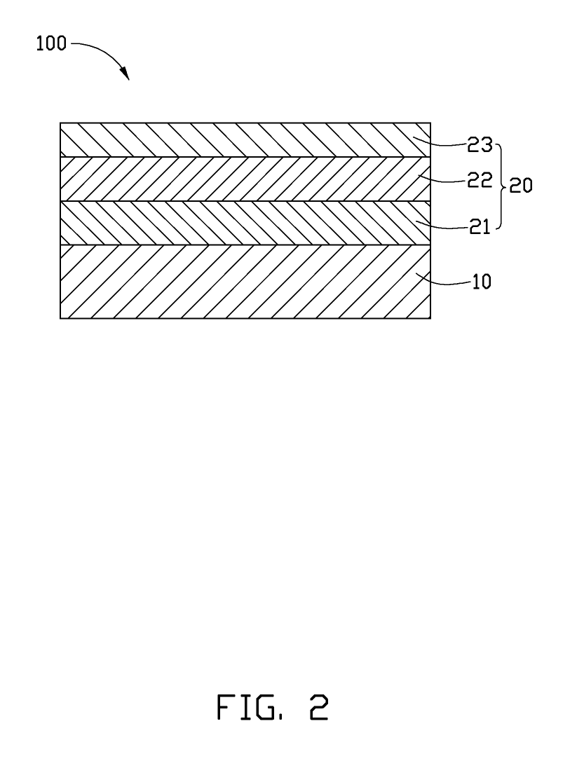

Referring to FIG. 2, a decorated layer 23 can also be disposed on the hard layer 22. The decorated layer 23 can color the surface of the hardened substrate 100. The decorated layer 23 can be paint or an organism layer. The decorated layer 23 can also include chromium compounds, such as, chromium carbide, chromium nitride, or combinations thereof. The chromium compounds can have high mechanical hardness and high wearing resistance to protect the hard layer 22 from being scratched.

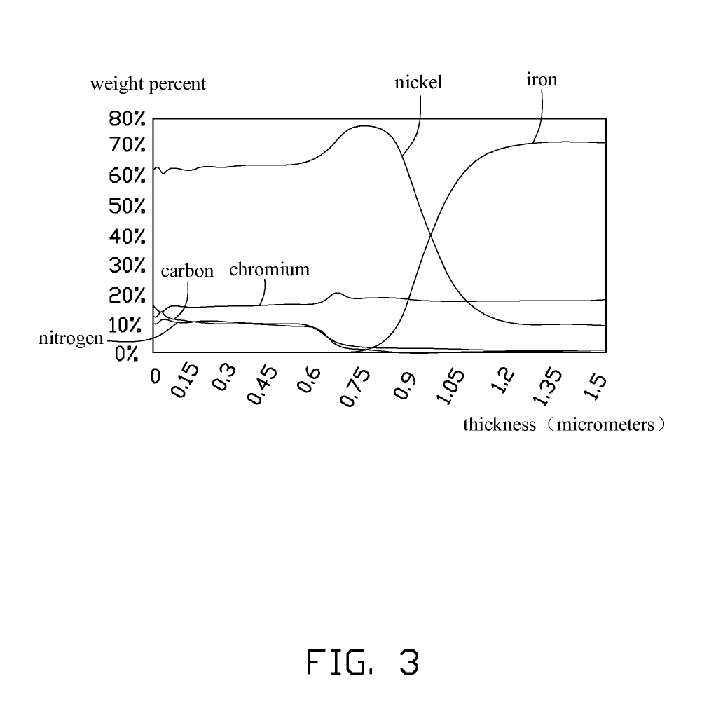

A depth profiling analysis of the surface hardened substrate 100 in FIG. 1 can be carried out by a glow discharge optical emission spectrometry (GD-OES). Materials in the hardened substrate 100, such as, iron, nickel, chromium, nitrogen and carbon have smooth curves as shown in FIG. 3. The materials can be distributed in different depths. The enhanced film 20 is a multilayer structure, however, the materials in the transition layer 21 or the base 10 can be distributed in the hard layer 22, and materials in the hard layer 22 can also be distributed in the transition layer 21. Therefore, the enhanced film 20 can be defined as an alloy film. One side of the alloy film facing the base 10 can include more transition metals, such as, nickel or chromium. The other side of the alloy film opposite the base 10 can include more nonmetals, such as, the nitrogen and the carbon to form other hard phases.

One embodiment of a method for making the surface hardened substrate 100 in FIG. 1 can include following steps:
S10, providing a base 10;
S20, forming a transition layer 21 on a surface of the base 10, the transition layer 21 comprising at least two kinds of transition metals; and
S30, forming a hard layer 22 on the transition layer 21, the hard layer 22 comprising a composite that comprises the at least two kinds of transition metals and a nonmetal.

In step S10, the base 10 can be cleaned. The cleaning can be performed by the following steps: S11, cleaning a surface of the base 10 with an ultrasonic in a solvent; and S12, plasma cleaning the base 10 with an inert gas in a vacuum environment.

In step S11, the solvent can be an organic solvent such as an acetone or an ethanol. In steps S12, the vacuum environment can be supplied by a chamber in a sputtering equipment. The inert gas can be argon or helium dispersed in the chamber. In one embodiment, the base 10 can be received in the sputtering equipment having a vacuum degree of about 3*10⁻⁵ Torres. The base 10 is bombarded with the pure argon in the sputtering equipment from about 3 minutes to about 10 minutes.

In step S20, the base 10 can have a temperature from about 100 degrees to about 200 degrees, to make the transition layer 21 firmly disposed on the base 10. The transition layer 21 can be formed on the base 10 by means of sputtering and formed by following step: S21, bombarding a sputtering alloy target including the at least two kinds of transition metals and forming the transition layer 21 on the surface of the substrate 100.

In step S21, the sputtering alloy target can be a Ni—Cr alloy target including nickel and chromium. The nickel in the Ni—Cr alloy target can have a weight percent from about 20 percent to about 80 percent. When the Ni—Cr alloy target is turned on for about 20 minutes to about 60 minutes, a Ni—Cr alloy layer having a thickness from about 100 nanometers to about 3 micrometers can be formed on the surface of the base 10.

In step S30, the hard layer 22 can be formed by means of sputtering and disposed by following steps: S31, introducing a carbonaceous gas and a nitrogenous to the transition layer 21; and S32, bombarding a sputtering alloy target that comprises the material of at least two transition metals.

In step S31, the carbonaceous gas can be acetylene or methane. The nitrogenous gas can be a nitrogen gas or an ammonia gas. In one embodiment, the carbonaceous gas is the acetylene, and the nitrogenous gas is the nitrogen gas.

In step S32, the at least two kinds of transition metals can react with the carbonaceous gas and the nitrogenous gas to form an alloy deposited on the transition layer 21. In one embodiment, the sputtering alloy target is the Ni—Cr alloy target, the nickel and the chromium can react with the carbonaceous gas and the nitrogenous to form a Ni—Cr—N—C alloy. The Ni—Cr—N—C alloy can be deposited on the transition layer 21 to form the hard layer 22.

Depending on the embodiment, certain of the steps of methods described may be removed, others may be added, and the sequence of steps may be altered. It is also to be understood that the description and the claims drawn to a method may include some indication in reference to certain steps. However, the indication used is only to be viewed for identification purposes and not as a suggestion as to an order for the steps.

It is to be understood that the above-described embodiments are intended to illustrate rather than limit the present disclosure. Any elements described in accordance with any embodiments is understood that they can be used in addition or substituted in other embodiments. Embodiments can also be used together. Variations may be made to the embodiments without departing from the spirit of the disclosure. The above-described embodiments illustrate the scope, but do not restrict the scope of the disclosure.

What is claimed is:

1. A surface hardened substrate comprising:
a base;
a transition layer disposed on a surface of the base, the transition layer comprising at least two kinds of transition metals; and
a hard layer disposed on the transition layer, the hard layer comprising a composite that comprises the at least two kinds of transition metals and a nonmetal.

2. The surface hardened substrate of claim 1, wherein the base comprises a metal or a composite.

3. The surface hardened substrate of claim 1, wherein the at least two kinds of transition metals are selected from the group consisting of nickel, chromium, rhodium, cobalt, manganese, titanium, tungsten, palladium, cadmium, zirconium, and combinations thereof.

4. The surface hardened substrate of claim 1, wherein the nonmetal is selected from the group consisting of nitrogen, carbon, and combinations thereof.

5. The surface hardened substrate of claim 1, wherein the transition layer is an alloy formed by nickel and chromium.

6. The surface hardened substrate of claim 5, wherein the nickel of the transition layer has a weight percent of about 20 percent to about 80 percent.

7. The surface hardened substrate of claim 1, wherein the hard layer is an alloy comprising nickel, chromium, nitrogen, and carbon.

8. The surface hardened substrate of claim 7, wherein the hard layer comprises a hard phase, the hard phase comprises the nitrogen and the chromium, or comprises the carbon and the chromium.

9. The surface hardened substrate of claim 7, wherein the nitrogen of the hard layer has a weight percent from about 1 percent to about 50 percent, the carbon of the hard layer has a weight percent from about 1 percent to about 50 percent, and the weight percent of the nitrogen plus the weight percent of carbon is in a range from about 1 percent to about 90 percent.

10. The surface hardened substrate of claim 1, wherein the transition layer has a thickness from about 500 nanometers to about 5 micrometers.

11. The surface hardened substrate of claim 1, further comprising a decorated layer disposed on the hard layer, wherein the decorated layer comprises a chromium compound.

12. The surface hardened substrate of claim 11, wherein the chromium compound is selected from the group consisting of chromium carbide, chromium nitride, and combinations thereof.

13. A surface hardened substrate comprising:
a base; and
an enhanced film disposed on a surface of the base, the enhanced film comprising an alloy layer comprising at least two kinds of transition metals;
wherein a side of the enhanced film opposite to the base comprises a nonmetal.

14. The surface hardened substrate of claim 13, wherein the base is a steel base.

15. The surface hardened substrate of claim 13, wherein the alloy layer is an alloy based on nickel and chromium.

16. A method for making a surface hardened substrate, comprising:
providing a base;
forming a transition layer on a surface of the base, the transition layer comprising at least two kinds of transition metals; and
forming a hard layer on the transition layer, the hard layer comprising a composite comprising the at least two kinds of transition metals and a nonmetal.

17. The method of claim 16, wherein the transition layer and the hard layer are formed by means of sputtering.

18. The method of claim 17, wherein the step forming the transition layer comprising:
bombarding a sputtering alloy target comprising the at least two kinds of transition metals, and forming the transition layer on the surface of the base.

19. The method of claim 17, wherein the step forming the hard layer comprising:
introducing a carbonaceous gas and a nitrogenous gas to the transition layer; and
bombarding a sputtering alloy target comprising the at least two kinds of transition metals.

20. The method of claim 19, wherein the carbonaceous gas is selected from the group consisting from an acetylene, a methane, and combinations thereof; the nitrogenous gas is selected from the group consisting from a nitrogen gas, an ammonia gas, and combinations thereof.
